(19) United States
(12) Patent Application Publication
(10) Pub. No.: US 2012/0096416 A1
(43) Pub. Date: Apr. 19, 2012

(54) HIGH-TEMPERATURE DEVICES ON INSULATOR SUBSTRATES

(76) Inventors: Chriswell G. Hutchens, Stillwater, OK (US); Roger L. Schultz, Aubrey, TX (US); Venkataraman Jeyaraman, Rancho Cordova, CA (US)

(21) Appl. No.: 13/335,523

(22) Filed: Dec. 22, 2011

Related U.S. Application Data
(62) Division of application No. 10/992,067, filed on Nov. 18, 2004.
(60) Provisional application No. 60/523,124, filed on Nov. 18, 2003.
(60) Provisional application No. 60/523,122, filed on Nov. 18, 2003.
(60) Provisional application No. 60/523,121, filed on Nov. 18, 2003.

(51) Int. Cl. G06F 17/50

(52) U.S. Cl. 716/102

(57) ABSTRACT

Semiconductor devices, logic devices, libraries to represent logic devices, and methods for designing and fabricating the same are disclosed. The semiconductor devices include a substrate comprising sapphire or diamond, an active layer disposed on the substrate, the active layer having a thickness tSi and comprising a channel region having a length L, where L/tSi is above 7 and an oxide layer disposed on the active layer.

### CROSS-REFERENCE TO RELATED APPLICATION

This application is a divisional of U.S. patent application Ser. No. 10/992,067, filed Nov. 18, 2004, entitled “High-Temperature Devices on Insulator Substrates,” which claims priority to commonly owned U.S. provisional patent applications: Ser. No. 60/523,124, filed Nov. 18, 2003, entitled “High-Temperature Magnetic Random Access Memory,” by Roger Schultz, Chris Hutchens, James J. Freeman, and Chia Ming Liu; Ser. No. 60/523,122, filed Nov. 18, 2003, entitled “Cell Library for VHDL Automation,” by Chris Hutchens and Roger Schultz; and Ser. No. 60/523,121, filed Nov. 18, 2003, entitled “SOS Charge Pump,” by Chris Hutchens and Roger L. Schultz. The contents of U.S. patent application Ser. No. 10/992,067, filed Nov. 18, 2004, entitled “High-Temperature Devices on Insulator Substrates,” are incorporated by reference herein.

### BACKGROUND

As activities conducted in high-temperature environments, such as well drilling, become increasingly complex, where the importance of including electronic circuits for activities conducted in high-temperature environments increases.

Semiconductor based components, including Complementary Metal Oxide Semiconductor (CMOS) devices, may exhibit increased leakage currents at high temperatures. For example, conventional bulk-silicon CMOS devices may exhibit increased leakage currents, and hence decreased resistances, in response to an increase in the environmental temperature of the device.

### BRIEF DESCRIPTION OF THE DRAWINGS

FIGS. 1-2 are flow charts of a system for designing one or more circuits

FIG. 3 is a cut away representation of a transistor.

FIGS. 4-5 are flow charts of a system for designing one or more circuits.

FIG. 6 is a schematic diagram of a NOR gate.

FIG. 7 is a schematic diagram of a NAND gate.

FIGS. 8-15 are I-V curves of transistors with sapphire substrates.

FIGS. 16-21 are flow charts of beta-matching systems.

FIG. 21 is a die-level diagram of a 2×2 Input-1 Output AND-OR gate.

FIGS. 23-24 are flow charts of a system for fabricating semiconductor devices.

FIGS. 25-29 are block diagrams of a transistor in stages of fabrication.

FIG. 30 is a flow chart of an example system for testing fabricated cells.

FIGS. 31-32 are flow charts example systems for designing a circuit using one or more entries from the cell library.

### DETAILED DESCRIPTION

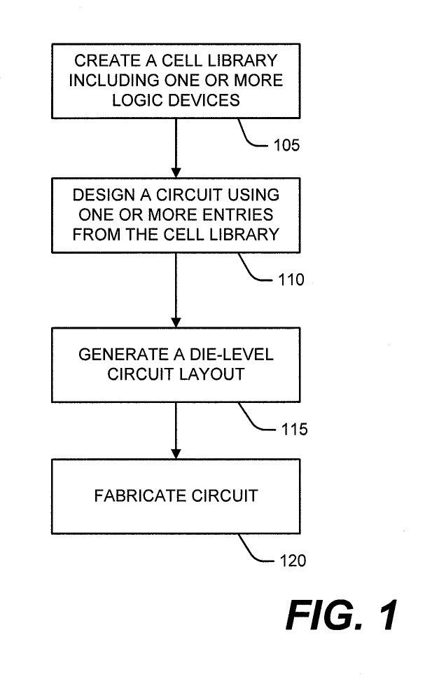

FIG. 1 shows an example system for creating, designing, and using a cell library. In general, a cell library is a collection of entries that represent circuits. The circuit represented by an entry in a cell library may be referred to as a cell. Each of the entries contains one or more characteristics of its circuit. Example entries may represent logic devices, such as a single logic gate, a group of two or more logic gates connected together, a sequential logic device, a multiplexer, or a demultiplexer.

In general a cell may include one or more semiconductor devices such as P-channel (NMOS) transistors and N-channel (PMOS) transistors. The transistors and other devices in the cell may be coupled to each other to form a circuit. Example circuits may include sequential and combinatorial logic devices. The terms “couple” or “couples,” as used herein are intended to mean either an indirect or direct connection. Thus, if a first device couples, or is coupled, to a second device, that connection may be through a direct connection, or through an indirect electrical connection via other devices and connections.

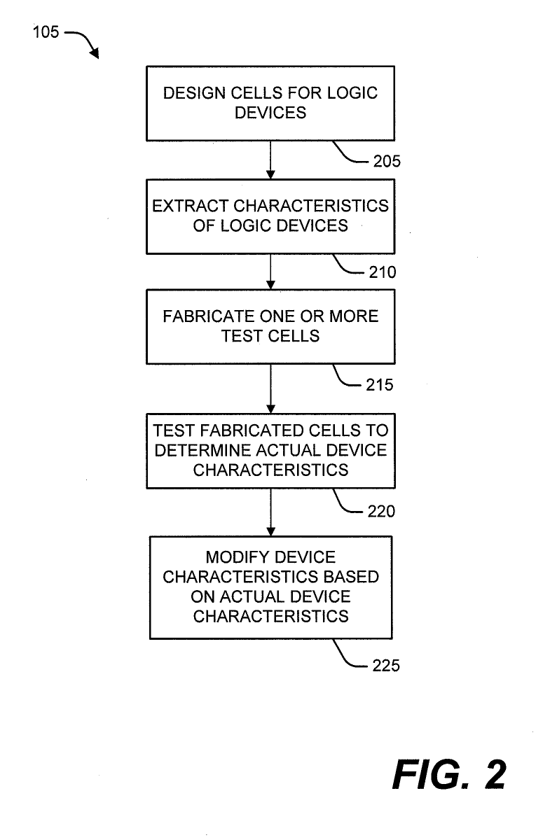

The example system creates a cell library with entries that include one or more logic devices (block 105, which is shown in greater detail in FIG. 2). The system may design a circuit using one or more entries from the cell library (block 110). The system may generate a die-level circuit layout of the circuit (block 115). The system may fabricate the circuit (block 120).

An example system for creating a cell library with entries that include one or more logic devices (block 105), is shown in FIG. 2. The system designs cells for logic devices (block 205). The system may extract characteristics of one or more of the logic devices created in block 205 (block 210). The system may fabricate one or more test cells (block 215). The system may test the fabricated cells to determine one or more actual device characteristics (block 220). The system may modify the device characteristics (determined in block 210), based on the actual device characteristics (block 225).

In example implementations, the system may perform one or more of blocks 205-225 two or more times to further refine the characteristics of the device. In other example implementations, the system may perform one or more of blocks 205-225 to achieve one or more desired characteristics of the device. For example, in some example implementations a user may want to limit a leakage current in the logic device and may perform one or more of blocks 205-225 until the desired leakage current is achieved. In another example implementation, the user may want to limit one or more switching speeds and may perform one or more of blocks 205-225 until the desired switching speeds are achieved.

The cells created in block 105 may be used in a high-temperature or radioactive environments. Such environments may include well-drilling, power generation, space applications, environments within or near a jet engine, or environments within or near an internal-combustion engine. The term well-drilling is not meant to be limited to oil-well drilling and may include any applications subject to a high temperature downhole environment, such as logging applications, workover applications, long term production monitoring applications, downhole controls, fluid extraction applications, measurement or logging while drilling applications. In general, switching speed is time for the output of a device to change in response to a change in one or more inputs to the device.

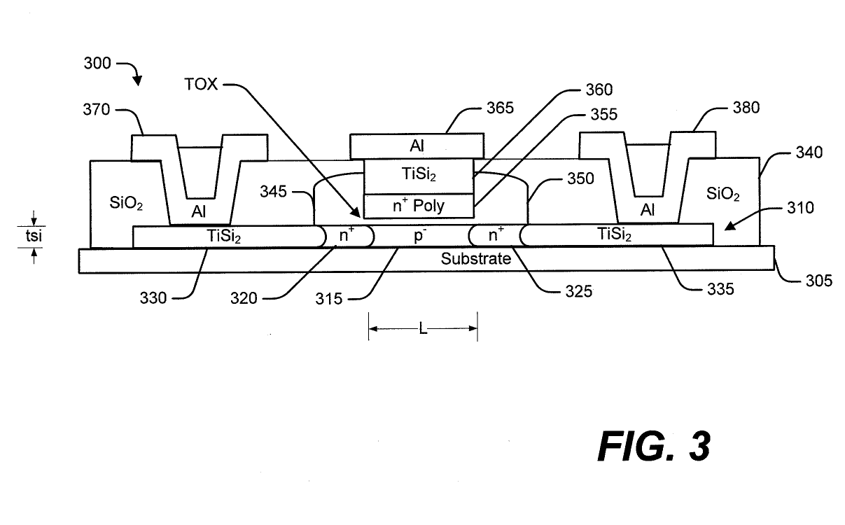

An example semiconductor device 300 that may be used by the system to construct logic gates is shown in FIG. 3. The semiconductor device 300 is a NMOS (P-channel) field effect transistor (FET). The semiconductor device includes a substrate 305. The substrate 305 may include an insulator to reduce leakage current. For example, the substrate 305 may include sapphire including Al₂O₃. The substrate 305 may include diamond.

The semiconductor device may include an active layer disposed on the substrate 305. For example, the semiconductor device 300 may include a silicon layer 310 disposed on the substrate 305. The silicon layer 310 may include one or more p regions, such as p− region 315. The silicon layer 310 may include one or more n regions, such as n+ regions 320 and 325. The silicon layer 310 may include one or more silicide regions such as TiSi₂ regions 330 and 335. The TiSi₂ regions 330 and 335 may be the drain and source of the transistor depending on which is biased to a higher voltage. The silicon layer 310 may be etched away outside TiSi₂ regions 330 and 335. The semiconductor device may include an oxide layer, such as the oxide layer 340. The oxide layer 340 may include one or more sidewalls such as sidewalls 345 and 350. The oxide layer 340 may include an oxide, such as SiO₂. The semiconductor device 300 may include one or more poly layers such as the n-poly layer 355. The semiconductor device may include one or more TiSi₂ layers, such as TiSi₂ layer 360. The semiconductor device may include a metal layer 365 in contact with the TiSi₂ layer 360. The semiconductor device may include one or more contact holes so that metal layers 370 and 380 may contact TiSi₂ regions 330 and 335, respectively. The metal layers may include one or more conductive materials. For example, the metal layers 365, 370, and 380 may include aluminum.

FIG. 3 also illustrates the dimensions of the device. The substrate 305 has a thickness. In certain implementations, the substrate may be thinner than 190 nm. The etched silicon layer 310 has a thickness tSi. The etched silicon layer 310 includes a channel region (p− region 315) that has a length L. The etched silicon layer 310 may also be referred to as an active layer. A portion of the oxide layer 340 with a thickness TOX separates the active layer 310 from the poly layer 355. The layers also include a width which is in the dimension perpendicular to the plane of the figure.

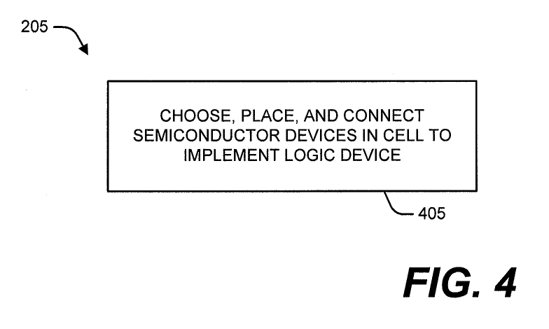

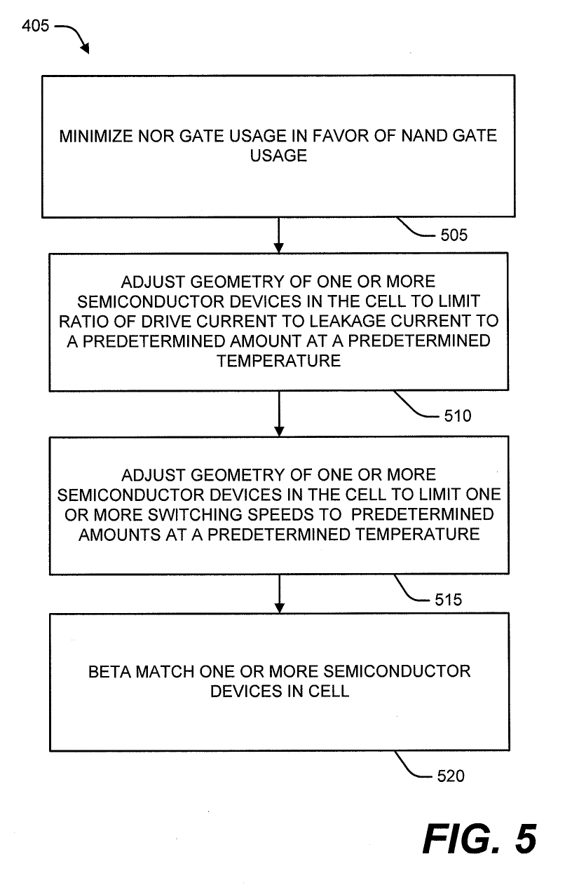

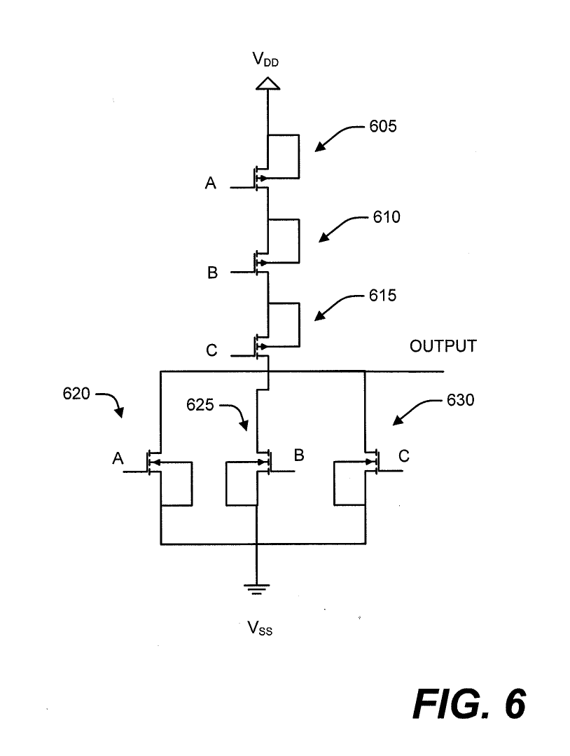

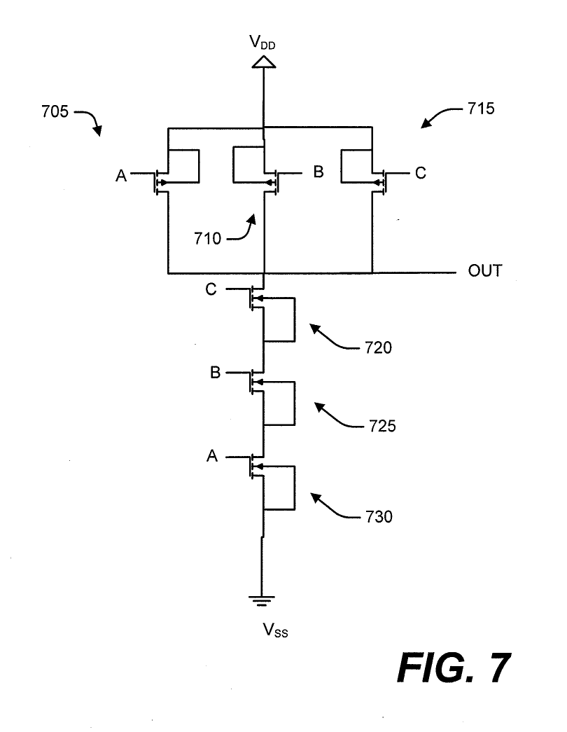

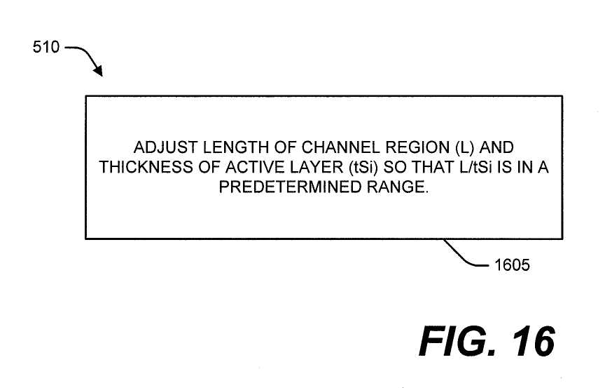

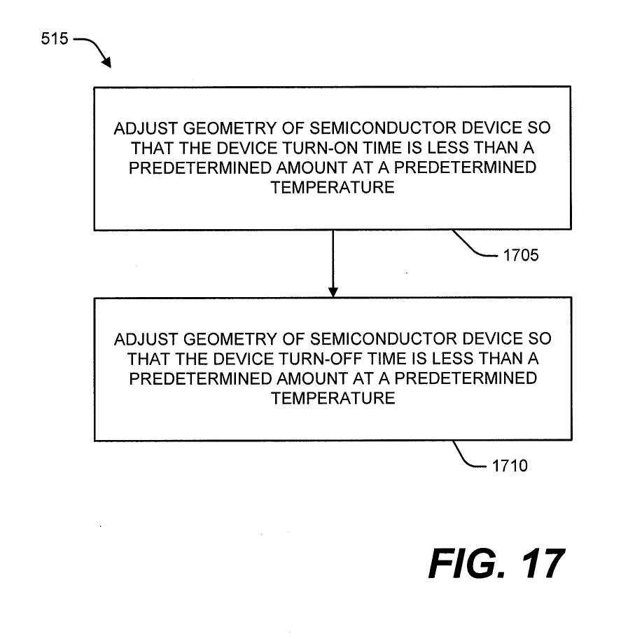

As shown in FIG. 4, designing cells for logic devices (block 205) includes choosing, placing, and connecting semiconductor devices in the cell to implement the logic device (block 405). FIG. 5 shows an example system for implementing block 405. The example system may minimize NOR gate usage in favor of NAND gate usage (block 505, which is discussed in greater detail with respect to FIGS. 6-7). The system may adjust the geometry of one or more of the semiconductor devices in the cell to limit a ratio I_{ON}/I_{OFF} to more than a predetermined amount at a predetermined temperature (block 510, which is shown in greater detail in FIG. 16). I_{OFF} is a leakage current that flows through the substrate (e.g., 305) of the semiconductor device. In general, the leakage current flows though the substrate even when the semiconductor device is not active (i.e., “off”). I_{ON} is a drive current that flows between the semiconductor drain (e.g., 330) and the source (e.g., 335), through the channel region 315 of the semiconductor device (e.g., 310) when the semiconductor device is active (i.e., “on”). The system may adjust the geometry of one or more semiconductor devices in the cell to limit one or more switching speeds to predetermined amounts at a predetermined temperature (block 515, which is shown in greater detail in FIG. 17).

In certain implementations, the system may favor certain semiconductor devices over others when implementing the logic device. A schematic of a NOR gate is shown in FIG. 6. The NOR gate includes P-channel transistors 605, 610, and 615 and N-channel transistors 620, 625, 630. The NOR gate receives inputs A, B, and C and produces an output that is the NORed value of A, B, and C.

A schematic of a NAND gate is shown in FIG. 7. The NAND gate includes P-channel transistors 705, 710, and 715 and N-channel transistors 720, 725, and 730. The NAND gate receives inputs A, B, and C and produces an output that is the NANDed value of A, B, and C.

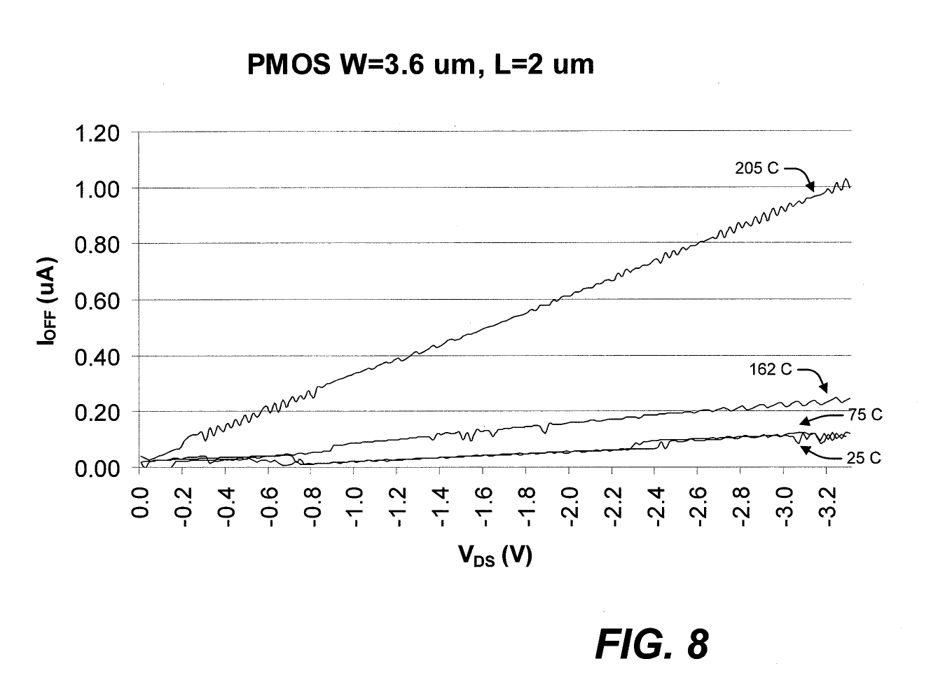

As will be discussed below with respect to FIGS. 8-15, the N-channel transistors produces more leakage current per volt across the drain and source of each transistor (V_{DS}) than an equally sized P-channel transistor. Therefore, in some example systems, NAND logic is preferred to NOR logic to reduce the voltage across the N-channel transistors and thereby reduce the leakage current. This reduction in voltage is due to the connection of the N-channel transistors in the NAND and NOR gates. The N-channel transistors 620, 625, and 630 in the NOR gate are connected in parallel, so they each drop the same voltage that is across the N-channel transistors 720, 725, and 730 as a group. The N-channel transistors 720, 725, and 730 in the NAND gate are connected in series, so the voltage drop across each N-channel transistor is a third of the voltage drop across the group of N-channel transistors.

FIGS. 8-15 demonstrate the difference in leakage currents between P- and N-channel transistors. The effects of changing the dimensions P- and N-channel transistors on their leakage current versus temperature are also shown in FIGS. 8-15.

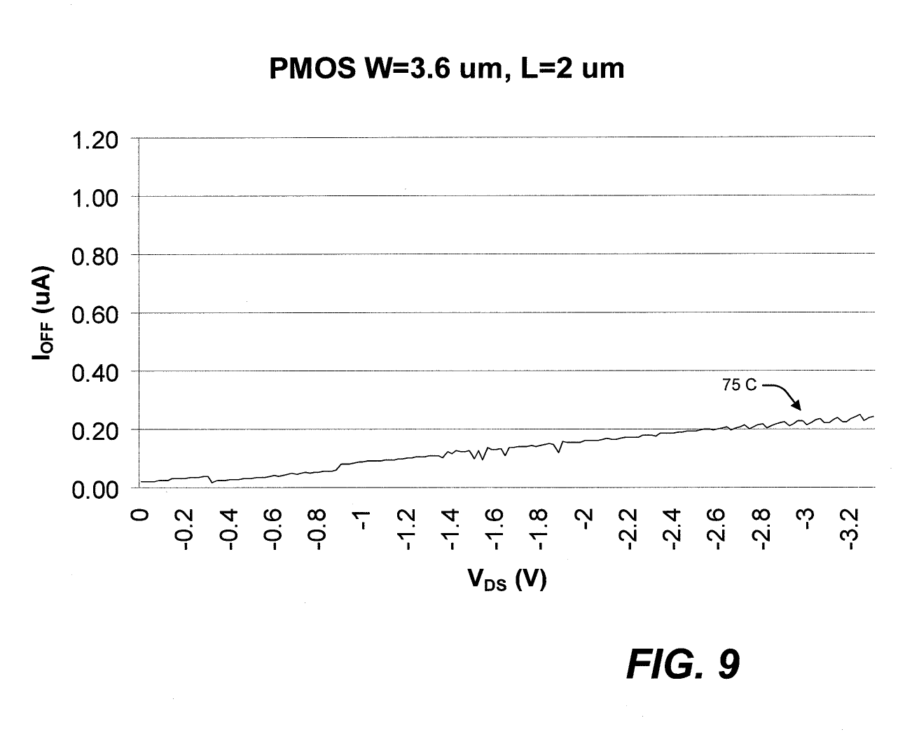

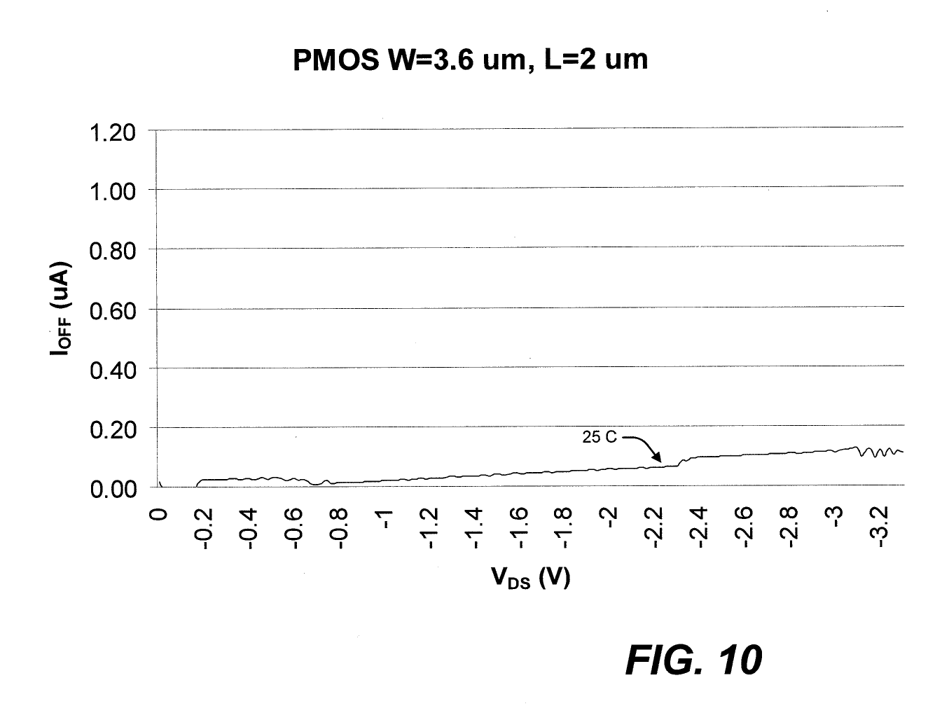

FIGS. 8-13 are plots of leakage current (I_{OFF}) (in micro-Amperes) versus drain-to-source voltage (V_{DS}) (in Volts) in Positive-Channel Metal Oxide Semiconductor (PMOS) transistors at different temperatures. These plots may be referred to as I-V curves. FIGS. 8-10 shows a series of I-V curves for a PMOS transistor with an active layer with a width of 3.6 μm and a channel length (L) of 2 μm that was fabricated using an SOS process. I-V curves are plotted for the example PMOS transistor at 25° C., 75° C., 162° C., and 205° C. are shown. The I-V curves for the 75° C. and 25° C. plots are shown alone in FIGS. 9 and 10, respectively, for differentiation between the two curves.

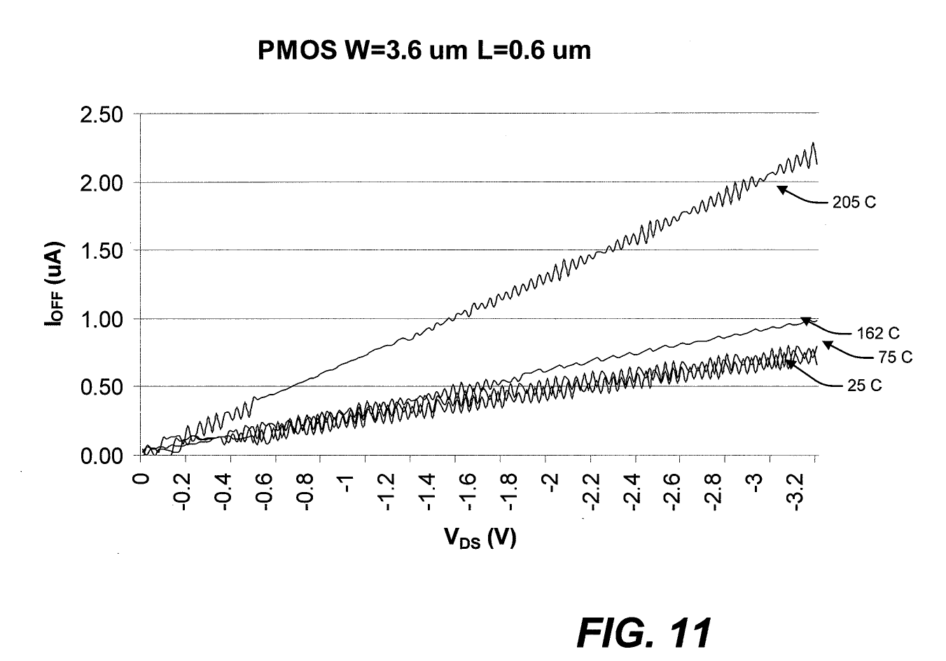

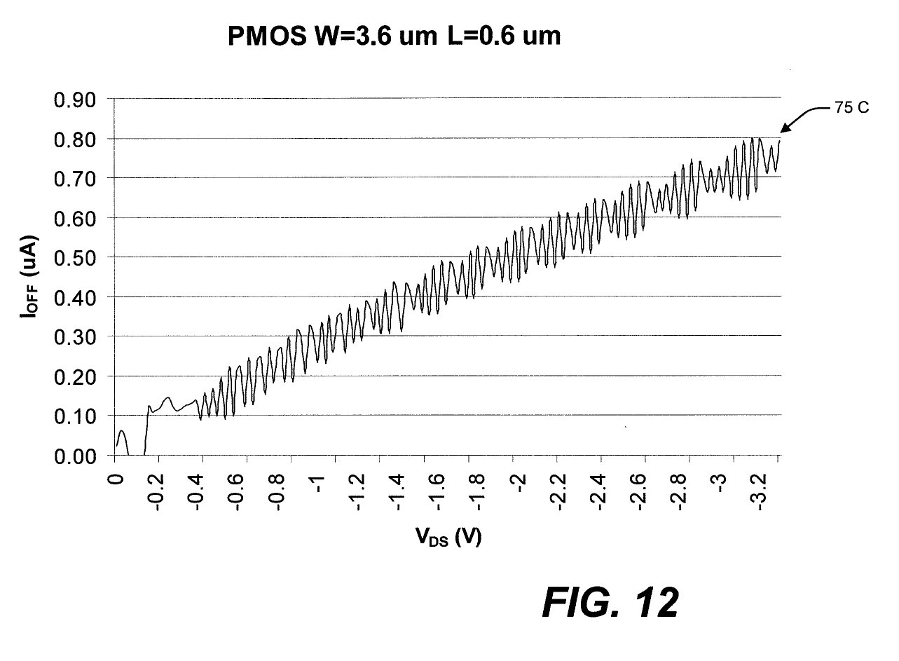

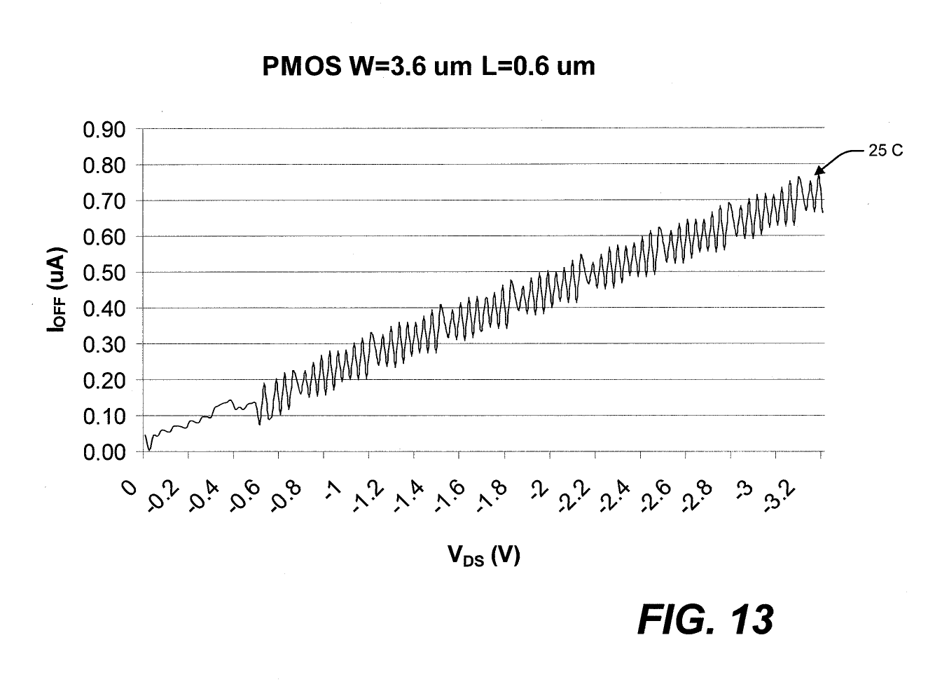

FIGS. 11-13 are I-V curves for a PMOS transistor with an active layer width of 3.6 μm and a channel length of 0.6 μm that was fabricated using a SOS process. The I-V curves show the leakage current (I_{OFF}) (in micro-Amperes) versus drain-to-source voltage (V_{DS}) (in Volts) for the PMOS transistor at 25° C., 75° C., 162° C., and 205° C. The curves for 75° C. and 25° C. are shown alone in FIGS. 12 and 13, respectively, for differentiation.

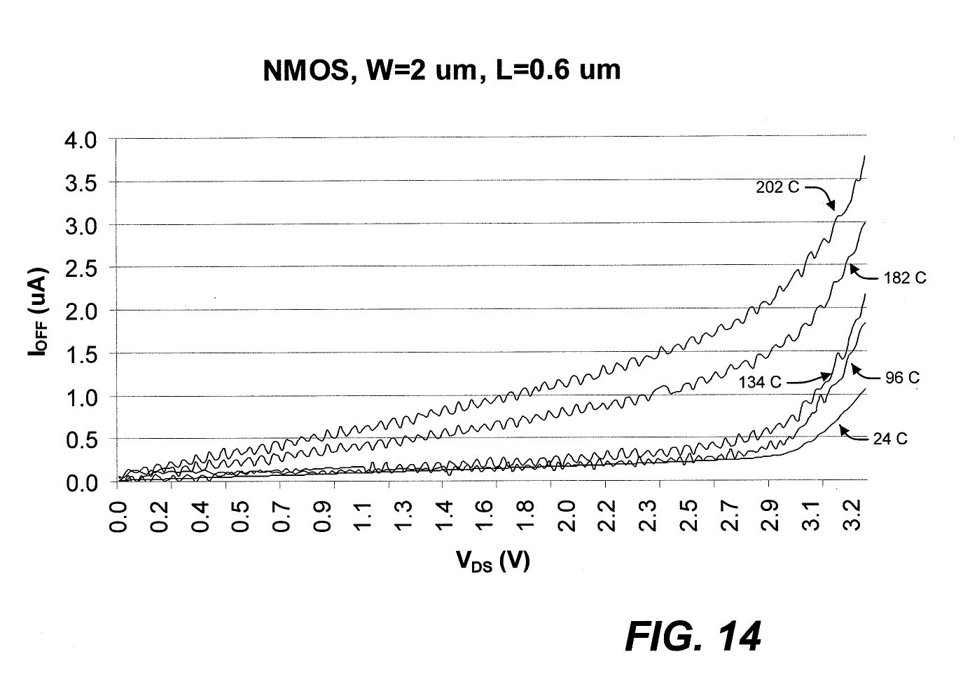

FIG. 14 shows a series of I-V curves for a Negative-Channel Metal Oxide Semiconductor (NMOS) transistor. The NMOS transistor has an active layer width of 2 μm and a channel length of 0.6 μm. The I-V curve shows the leakage current (I_{OFF}) (in micro-Amperes) versus drain-to-source voltage (V_{DS}) (in Volts) for the NMOS transistor at 24° C., 96° C., 134° C., 182° C., and 202° C.

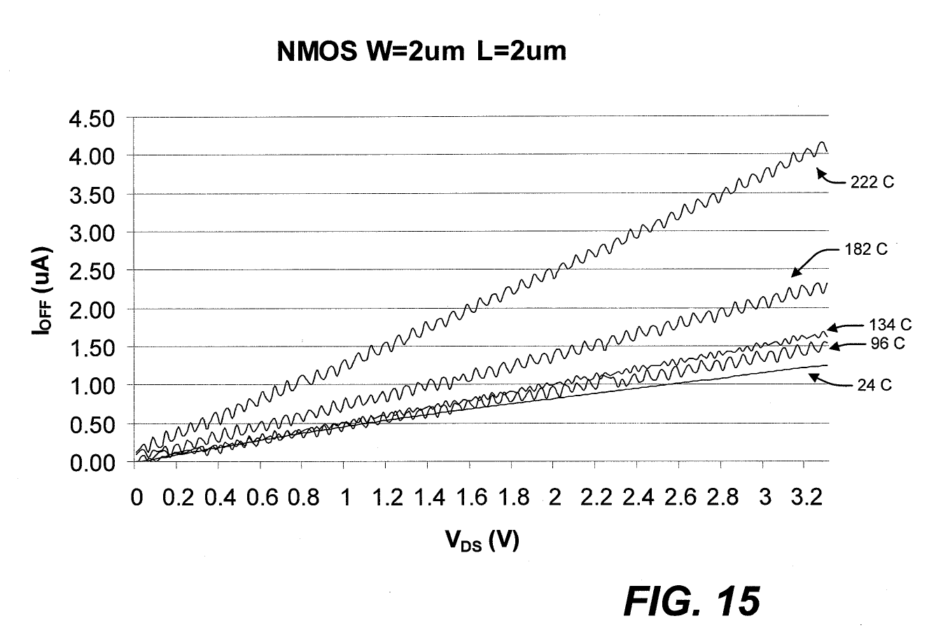

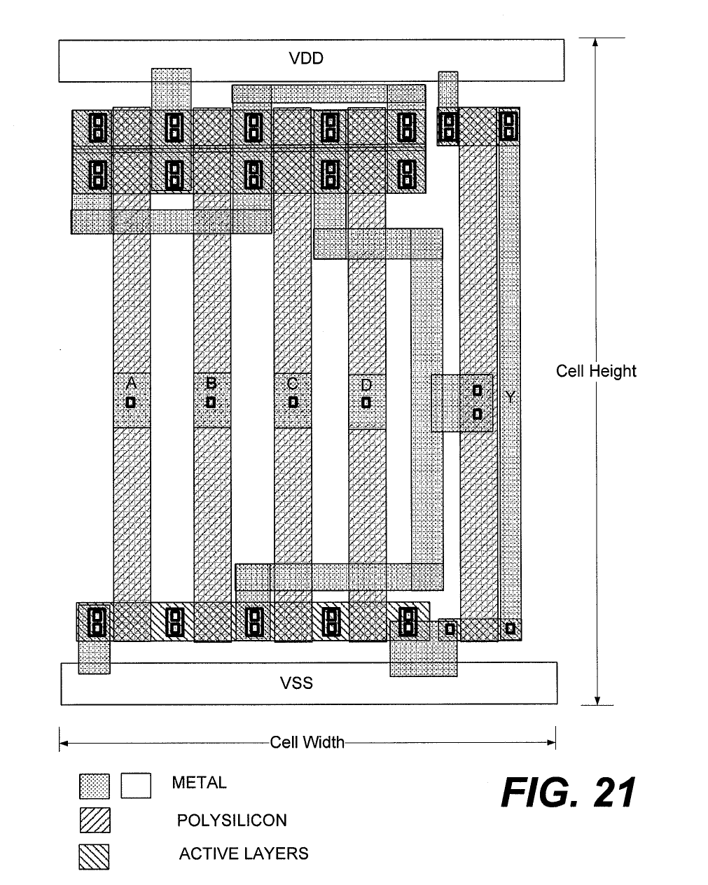

FIG. 15 shows a series of I-V curves for a Negative-Channel Metal Oxide Semiconductor (NMOS) transistor (as in FIG. 21). The NMOS transistor has an active layer width of 2 μm and a channel length of 2 μm. The I-V curve shows the leakage current (I_{OFF}) (in micro-Amperes) versus drain-to-source voltage (V_{DS}) (in Volts) for the NMOS transistor at 24° C., 96° C., 134° C., 182° C., and 222° C.

The I-V curves from FIGS. 8-15 show that the N-channel transistors have a much greater leakage current than P-channel transistors, where the transistors have the same dimensions and where the leakage current is measured at the same temperature. For example compare the curves for the P-channel transistor with an active layer width of 3.6 μm and a channel length of 2 μm at 205° C. (FIG. 8) with the N-channel transistor with the same dimension at 222° C. (FIG. 14). The leakage current for the N-channel transistor where V_{DS}=3 V is more than twice the leakage current for the P-channel transistor where V_{DS}=−3 V.

The characteristics of the N-channel and P-channel transistors shown in FIGS. 8-15 may be considered when designing cells for the logic devices. For example, the temperature-dependant characteristics of the NMOS and PMOS transistors may be considered when determining the gate lengths and widths of the transistors in a logic device. In another example, the temperature-dependant characteristic of the NMOS and PMOS transistors may be considered when determining whether to use PMOS- or NMOS-logic for portions of the a logic device.

FIG. 16 shows an example system for altering the geometry of the semiconductor device to limit I_{ON}/I_{OFF} to more than a predetermined amount at a predetermined temperature (block 510). The semiconductor device may be a transistor, a diode, or another semiconductor device. The example system adjusts the length of the channel (L) and the thickness of the active layer (tSi), so that L/tSi is in a predetermined range. In certain example systems the predetermined range may be above 3 or 7. In one example system the predetermined range may be between 7 and 30. In another example system the predetermined range may be from 11.8 to 25. In another example system L/tSi may be about 17.7.

Another example system may alter two or more of tSi, TOX, L, or one or more other dimensions of the semiconductor device so that I_{ON}/I_{OFF} is greater than a minimum value for temperatures up to a predetermined temperature.

For example, the system may alter the dimensions of a semiconductor device so that its I_{ON}/I_{OFF} is greater than 100 for temperatures up to 125° C. In another example, the system may alter the dimensions of a diode so that its I_{ON}/I_{OFF} is greater than 1000 for temperatures up to 125° C. In another example, the system may alter the dimensions of a diode so that its I_{ON}/I_{OFF} is greater than 10,000 for temperatures up to 125° C. In another example, the system may alter the dimensions of a diode so that its I_{ON}/I_{OFF} is greater than 100 for temperatures up to 240° C. In another example, the system may alter the dimensions of a diode so that its I_{ON}/I_{OFF} is greater than 100, 1,000, or 10,000 for temperatures up to 240° C. In another example, the system may alter the dimensions of a diode so that its I_{ON}/I_{OFF} is greater than 100, 1000, or 10,000 for temperatures up to 300° C.

In certain example implementations, the P-channel transistors and N-channel transistors may have different dimensions to achieve approximately equal I_{ON}/I_{OFF} ratios for the P-channel transistors and N-channel transistors.

FIG. 17 shows an example system for altering the geometry of the semiconductor device to limit one or more switching speeds (block 515, FIG. 5). The system may adjust the geometry of a semiconductor device to limit the turn-on time tₒₙ of the device to a maximum turn-on time (block 1710). The semiconductor device may be a diode, a P-channel transistor, an N-channel transistor, or another semiconductor device. Likewise, the system may adjust the geometry of the semiconductor device to limit the turn-off time t_{off} of the device to a maximum turn-off time. In some implementations, the system will perform both of blocks 1705 and 1710. In other implementations, the system may only perform one of blocks 1705 or 1710.

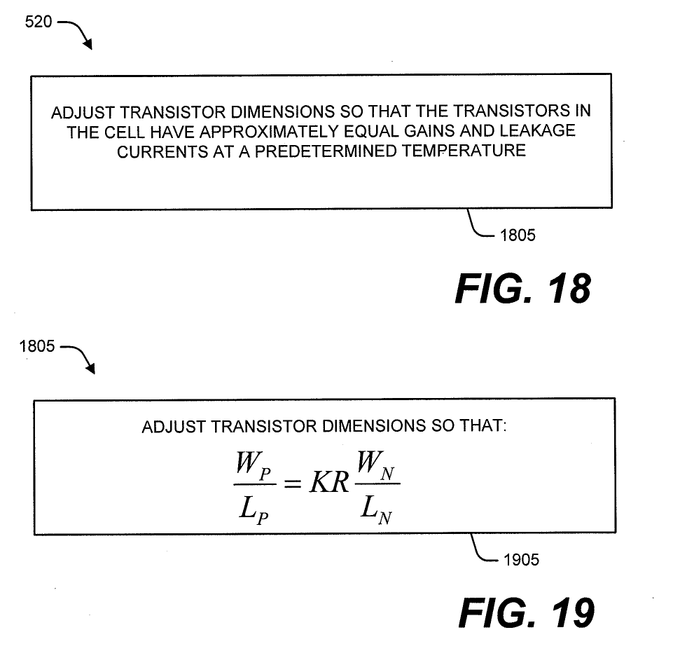

FIG. 18 shows an example system for beta-matching one or more P-channel transistors and N-channel transistors in a cell (block 520). The system may adjust one or more dimensions of the transistors so that the transistors have approximately equal gains and leakage currents at a predetermined temperature. In one example system the predetermined temperature is 125° C. In another example system the predetermined temperature is 240° C. In another example system the predetermine temperature may be between 125° C. and 300° C.

An example system for beta-matching according to block 1805 is shown in FIG. 19. In one example design, optimal noise characteristics may be maintained by choosing a higher leakage current over a higher speed performance. In one implementation, the following equation may be used to beta match a device:

$$\frac{{W}_{P}}{{L}_{P}} = KR \frac{{W}_{N}}{{L}_{N}} ,$$

where W is the width and L is the length of the channel, W/L is the width to length ratio of the device, and KR is the ratio of mobility electrons to mobility holes. In one example, KR may range from 1.5 to 3. Further, the mobility and leakage current of an N-channel transistor may be higher for a given gate length L than that of a P-channel transistor. Selecting a P-channel transistor having a channel length Lₚ and an N-channel transistor having a channel length Lₙ to minimize leakage current and maximize speed of the device, and selecting KR at a given temperature to determine the desired Wₚ to Wₙ ratio may result in a device having optimal leakage performance or having optimal leakage current versus device speed. In one example, if KR=1.5, Lₚ=0.8 μm, Wₚ=Wₙ, Lₙ may be selected to be 1.2 μm. In another example, if KR=2, Lp=0.8 μm, Wp/Wn=1.6, Lₙ may be selected to be 1.2 um.

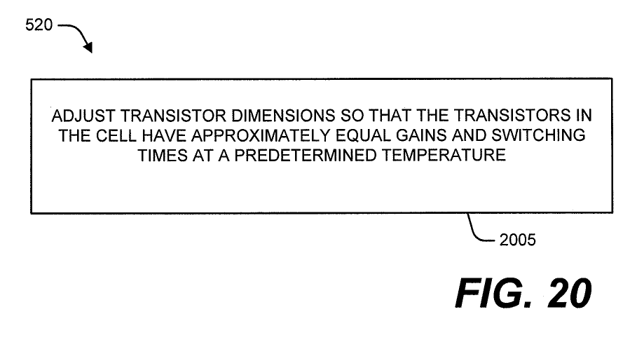

FIG. 20 shows an example system for beta-matching one or more P-channel transistors and N-channel transistors in a cell (block 520). The system may adjust one or more dimensions of the transistors so that the transistors have approximately equal gains and switching times at a predetermined temperature. In one example system, one or more of the P-channel transistors have a switching time tₛ₋ₚ and the N-channel transistors have a switching time tₛ₋ₙ. In one example system, tₛ₋ₚ and tₛ₋ₙ are turn-on times for the transistors. In another example system and tₛ₋ₚ and tₛ₋ₙ are turn-off times for the transistors. In another example system tₛ₋ₚ is a turn-on time and tₛ₋ₙ is a turn-off time. In another example system tₛ₋ₚ is a turn-off time and tₛ₋ₙ is a turn-on time. In one example system, the predetermined temperature is less than or equal to 125° C. In another example system the predetermined temperature is less than or equal to 240° C. In another example system the predetermined temperature is less than or equal to 300° C.

An example die-level layout of a cell for a 2×2 Input-1 Output AND-OR logic device is shown in FIG. 21. The cell has a cell height and a cell width. The cell height may also be referred to as the pitch of the cell. In some implementations, all of the cells have equal cell heights to facilitate cell connection. In some implementations, all of the cells have a width that is a multiple of a width unit (gₓ). This implementation allows the cells to be laid out as a grid, which may make sizing the cells easier. Metal layers, polysilicon layers, and active layers are shown as denoted in the legend. The smaller squares represent vias, contacts, or pins.

FIG. 22 shows an example system for extracting the characteristics of one or more logic devices (block 210). The logic device has one or more states, defined by one or more signals input to the logic device and one or more signals output from the logic device. The system may determine one or more timing characteristic of the cell (block 2205). The timing characteristics may include one or more transition times between states. These transitions times may be referred to as intrinsic delays in the logic device. The system may determine one or more transition times for changes in an input signal that cause an output of the logic device to change from a low logic state to a high logic state (tpLH). The system may determine one or more transition times for changes in an input signal that cause an output signal to transition from the high logic state to the low logic state (tpHL). The system may determine one or more input impedances for one or more of the inputs to the logic device (block 2210). The system may determine one or more cell dimensions, such as height and width (block 2215). The system may determine the cell area (block 2220). The one or more cell characteristics may be stored in one or more files which may be associated with the cell entry.

The values determined in block 210 may be recorded to characterize the logic device cell. In one example system, the values are included in a hardware design language description of the logic device cell. For example, one more VHSIC Hardware Description Language (VHDL) instructions or Verilog instructions may be generated to describe the device. These instructions may form a cell library entry for the cell.

In one example system, the following VHDL statements may be used to define the behavioral characteristics of a 3×3 AND-OR gate:

module andor(Y,A,B,C,D,E,F);

output Y;
input A, B, C, D, E, F;
assign Y = ((A & B & C) | (D & E & F));

endmodule

In the example above, A, B, C, D, E, and F are inputs and Y is the output of the gate. A netlist for the gate may also be generated by the system. For example, the following statements may be used to generate a netlist for the 3×3 AND-OR gate:

module andor(Y, A, B, C, D, E, F);

output Y;
input A;
input B;
input C;
input D;
input E;
input F;
aorf2301 i_0(.A(E), .B(D), .C(F), .D(B), .E(A), .F(C), .Y(Y));

endmodule

Where “aorf2301” is a module or library name for the 3×3 AND-OR gate.

The layout of the connection within the library cell, such as aorf2301 may be performed by hand or using automated layout tools. In certain example systems, the layout may be constrained by one or more design rules.

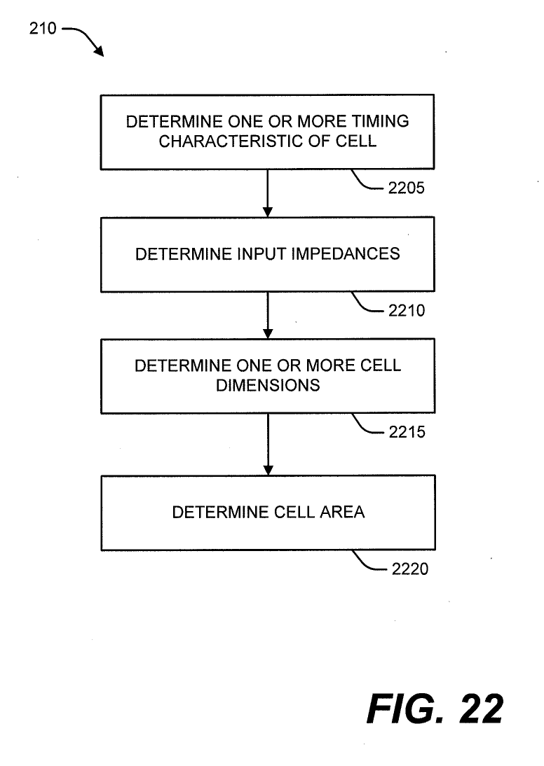

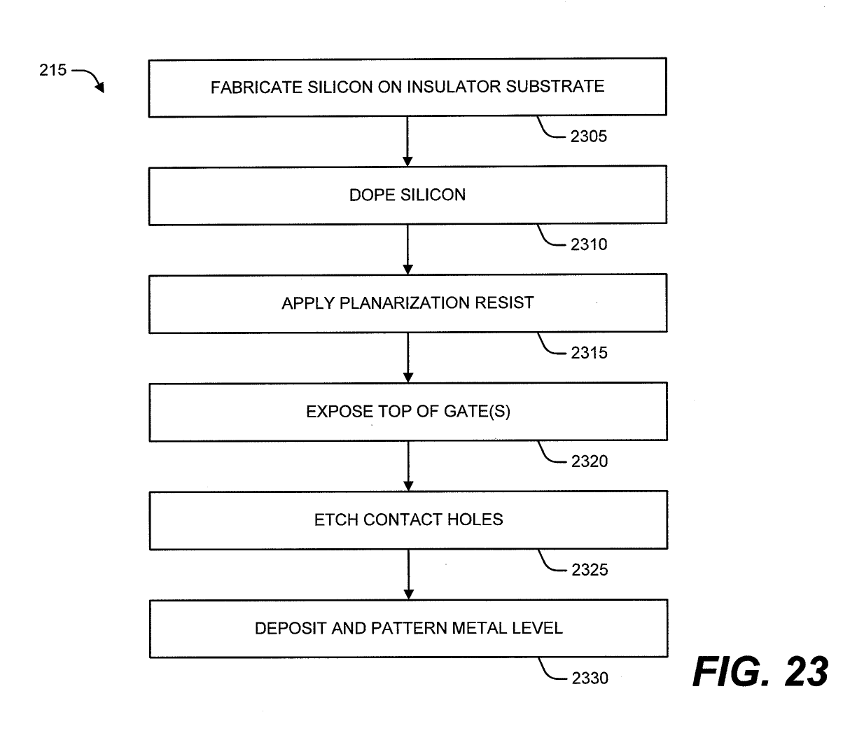

An example system for fabricating one or more test cells (block 215, FIG. 2) is shown in FIG. 23. Although the example system shown in FIG. 23 is for fabricating a transistor, it may be generalized to fabricate other devices on the substrate. The system may fabricate a silicon layer on the insulator substrate (block 2305). The system may dope the silicon to create one or more p regions and one or more n regions (block 2310). The system may apply a planarization resist to one or more portion of the device (block 2315). The system may planarize the device to expose the top of one or more gates in the device (block 2320). The system may etch more or more contact holes to connect one or more portions of the device to a metal layer (block 2325). The system may deposit and pattern the metal layer (block 2330).

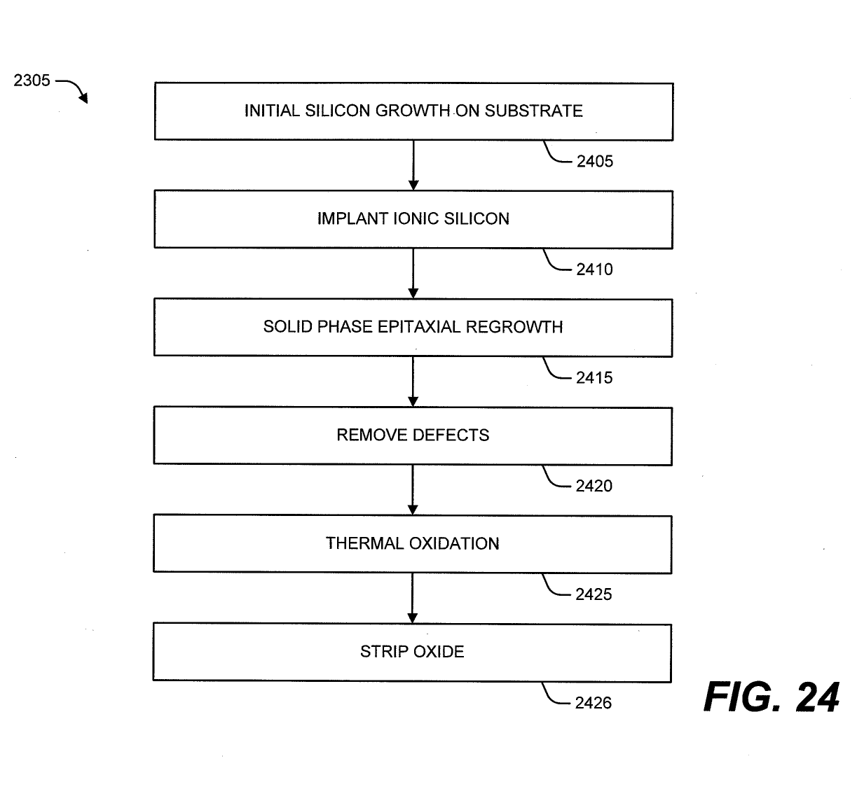

An example system for fabricating a silicon layer on an insulator substrate (block 2305) is shown in FIG. 24. The example system shown in FIG. 24 may create a thin-film layer of silicon on the insulator substrate. The system may perform an initial silicon grown on the substrate (block 2405). This initial growth may be performed by chemical vapor deposition. The system may implant an ionic silicon layer (e.g., positively charged) on the initial silicon layer (block 2410). The system may anneal the silicon layer by facilitating a solid phase epitaxial regrowth (block 2415). This process may be performed at an elevated temperature, for example at a temperature of about 550° C. The system may also anneal the silicon layer by removing defects (block 2420). This removal of defects may also be performed at an elevated temperature, for example at a temperature of about 900° C. The system may cause the silicon layer to undergo thermal oxidation to form an oxide layer (e.g., SiO₂) on the silicon layer (block 2425). The system may then strip the oxide layer from the silicon layer (block 2430).

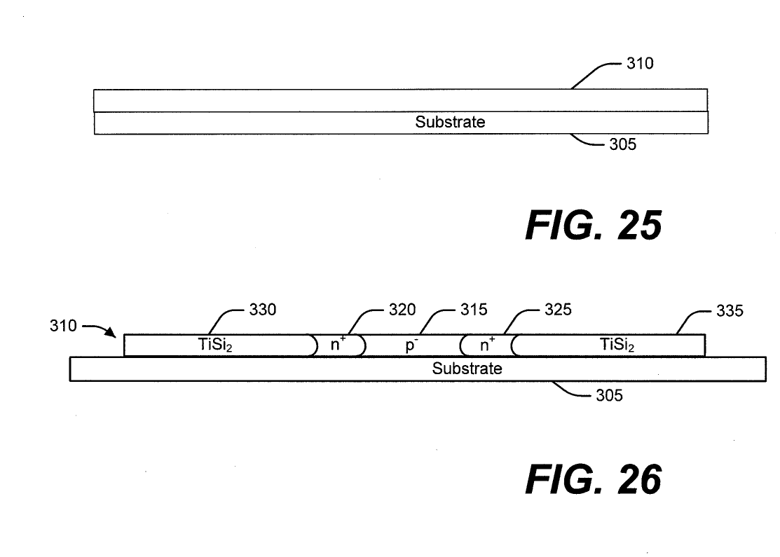

FIGS. 25-28 and 3 show an example device (e.g., a transistor) in phases of fabrication according to the system shown in FIG. 17. FIG. 25 shows the example device after the silicon layer 310 is fabricated on the insulator substrate 305. The insulator substrate 305 may exhibit a high resistance at an elevated temperature. Example substrates may include diamond and sapphire. Because of the high resistance of the insulator substrate 305 at elevated temperatures, devices fabricated on the insulator substrate 305 may exhibit lower leakage currents at elevated temperatures than devices fabricated on substrates with low resistance at elevated temperatures.

FIG. 26 shows the example device after one or more regions of the silicon layer 310 are doped (FIG. 23, block 2310). The silicon layer 310 may include one or more p-regions (e.g., p-wells), such as p-region 315. The silicon layer 310 may include one or more n-regions (e.g., n-wells), such as n-regions 320 and 320. The silicon layer may include one or more TiSi₂ regions such as TiSi₂ regions 330 and 335. The silicon layer may be etched away outside TiSi₂ regions 330 and 335.

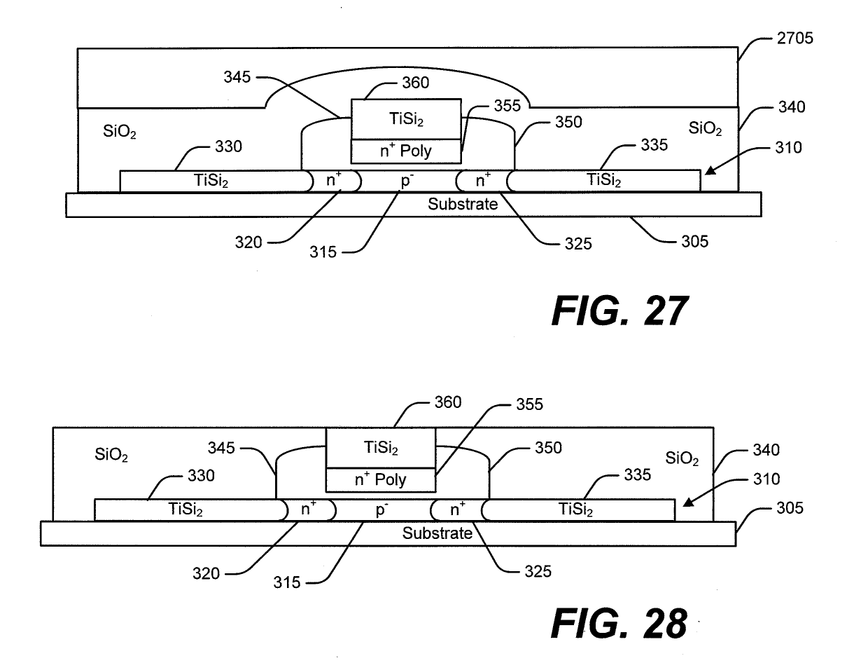

FIG. 27 shows the example device after additional semiconductor layers are formed and a planarization resist is applied to the device (FIG. 23, block 2315). One or more poly layers such as the n-poly layer 355 may be fabricated on the device. One or more TiSi₂ layers, such as TiSi₂ layer 360 may be fabricated on the device. A oxide layer, such as the SiO₂ layer may be applied to the device. The Oxide layer 340 may include one or more sidewalls such as SiO₂ sidewalls 345 and 350. The planarization resist 2705 may be spun onto the device.

FIG. 28 shows the example device after planarization (FIG. 23, block 2320). The planarization may expose one or more gates, such as the top of TiSi₂ layer 360. FIG. 3 shows the example device after one or more contact holes are etched (block 2325) and a metal layer is deposited and patterned (block 2330). In the example system, contact holes may be etched so that metal layers 370 and 380 may contact TiSi₂ regions 330 and 335, respectively. A metal layer 365 may also be deposited and patterned to contact TiSi₂ layer 360. The metal layers may include one or more conductive materials. For example the metal layers 330, 335, and 365 may include aluminum.

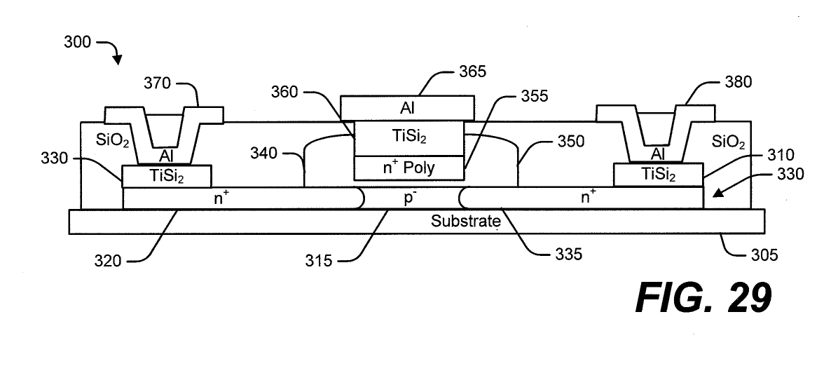

FIG. 29 shows another example device. In the device shown in FIG. 29, the silicide layers 310 and 330 may be disposed on, or partially within, the active layer 330.

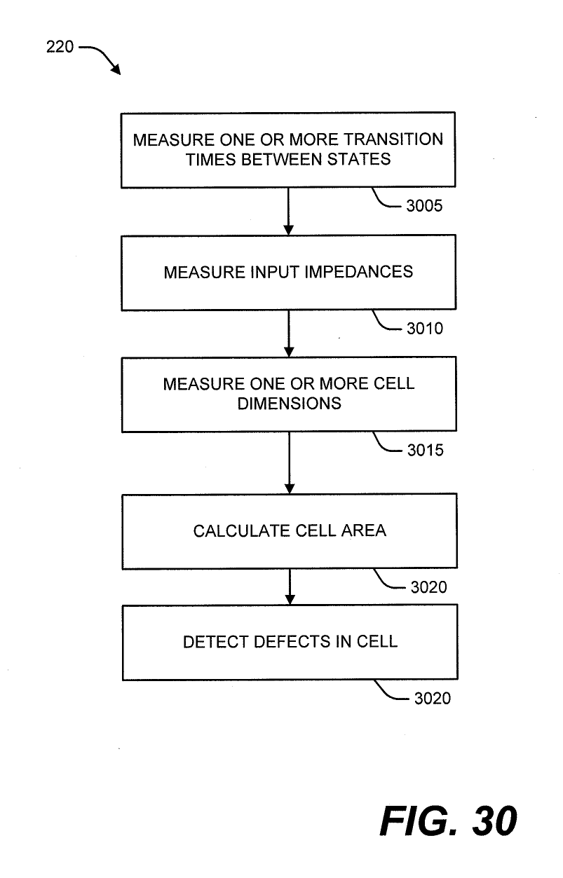

An example system for testing the fabricated cells to determine actual device characteristics (block 220, FIG. 2) is shown in FIG. 30. The system may measure one or more transition times between states (block 3005). The system may measure one or more input impedances (block 3010). The system may measure one or more cell dimensions (block 3015), and calculate the cell area (block 3020). The system may also test the cells for defects (block 3025). Based on these measurements, the system may modify the device characteristics (block 225, FIG. 2). This may include altering the VHDL or Verilog instructions that represent the cell entry in the cell library.

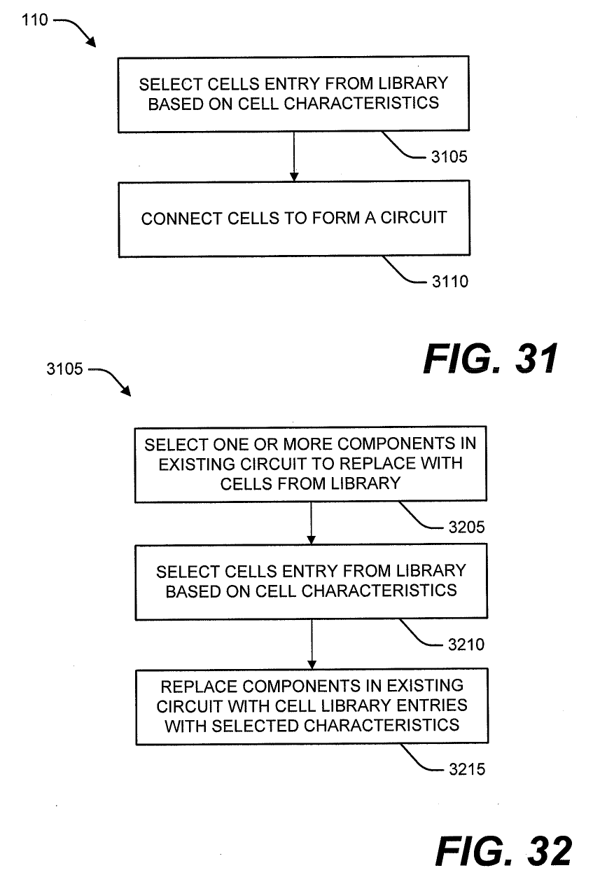

FIG. 31 shows an example system for designing a circuit using one or more entries from the cell library (block 110). The user may select one or more entries from the cell library based on the characteristics of the cell entries (block 3105). The user may then connect the cells to form a circuit (block 3110).

The cell characteristics may include, for example, the type of the logic device in the cell entry (e.g., whether it is an AND gate or a multiplexer), one or more input impedances of the logic cell, or one or more dimensions of the logic cell. In some example systems, the system may perform a search for the desired functionality and choose from one or more returned entries.

Circuit design using the cell library may not always start from scratch. For example, FIG. 32 shows an example system for selecting cell entries from the library based on cell characteristics (block 3105). The system may select one or more components in an existing circuit to replace with entries from the cell library (block 3205). The system may then select entries from the library based on the cell characteristics (block 3210). The system may then replace the selected components in the existing circuit with entries having the selected characteristics (block 3215).

The system discussed above may be useful to convert non-high temperature circuits into high temperature circuits in a quick manner. In some implementations, the system may plug a cell library entry into an existing circuit design.

The system may generate a die-level circuit layout from the logic-device level layout provided by the user (block 115). The system may fabricate the circuit (block 120) as described above with respect to FIGS. 23-28.

Therefore, the present invention is well-adapted to carry out the objects and attain the ends and advantages mentioned as well as those which are inherent therein. While the invention has been depicted, described, and is defined by reference to exemplary embodiments of the invention, such a reference does not imply a limitation on the invention, and no such limitation is to be inferred. The invention is capable of considerable modification, alternation, and equivalents in form and function, as will occur to those ordinarily skilled in the pertinent arts and having the benefit of this disclosure. The depicted and described embodiments of the invention are exemplary only, and are not exhaustive of the scope of the invention. Consequently, the invention is intended to be limited only by the spirit and scope of the appended claims, giving full cognizance to equivalents in all respects.

What is claimed is:

1. A non-transitory computer readable medium, having a computer program stored thereon, including a library, for designing one or more electronic circuits, comprising executable instructions that case a computer to represent:
one or more cells, each including further executable instructions to represent a logic device model, where the logic device model comprises:
a substrate comprising sapphire;
one or more P-channel transistor models comprising a first portion of the substrate, where each P-channel transistor model is characterized by a gain βₚ and a leakage current I_{OFF-P};
one or more N-channel transistor models coupled to the one or more P-channel transistor models, where the N-channel transistors comprising a second portion of the substrate, where each N-channel transistor is characterized by a gain βₙ and a leakage current I_{OFF-N}; and
where, at a predetermined temperature:
βₚ≈βₙ; and
I_{OFF-P}≈I_{OFF-N}.

2. The library of claim 1, where the predetermined temperature is between 125° C. and 300° C.

3. The library of claim 1, where one or more of the P-channel transistor models are connected in parallel with one or more of the N-channel transistor models.

4. The library of claim 1, where one or more of the P-channel transistor models are connected in series with one or more of the N-channel transistor models.

5. The library of claim 1, where:
each of the P-channel transistor models comprises an active layer comprising a channel region having a length L_{P} and a thickness tSi_{P} and a width W_{P};
each of the N-channel transistor models comprises an active layer comprising a channel region having a length L_{N} and a thickness tSi_{N} and a width W_{N}; and
where, at the predetermined temperature:
$$\frac{{W}_{P}}{{L}_{P}} = KR \frac{{W}_{N}}{{L}_{N}} ,$$
where KR is a ratio of an electron mobility to a hole mobility at the predetermined temperature.

6. The library of claim 1, where the active layer has a thickness tSi and where L_{P}/tSi is between 11.8 and 25.

7. The library of claim 1, where the active layer has a thickness tSi and where L_{P}/tSi is about 17.7.

8. The library of claim 1, where the active layer has a thickness tSi and where L_{N}/tSi is between 7 and 30.

9. The library of claim 1, where the active layer has a thickness tSi and where L_{N}/tSi is between 11.8 and 25.

10. The library of claim 1, where the active layer has a thickness tSi and where L_{N}/tSi is about 17.7.

11. The library of claim 1, where the logic device model further comprises:
one or more inputs;
one or more outputs; and
the logic device model being characterized by:
a set of one or more states based on:
one or more input signals applied to the one or more inputs;
one or more output signals output to the one or more outputs; and
a set of one or more transition times to transition from a first state to a second state at the predetermined temperature.

12. The library of claim 1, where the logic device model further comprises:
one or more inputs, each characterized by an impedance.

13. The library of claim 1, where the logic device model is in a cell model having a height, a width, and an area.

14. The library of claim 1, where the executable instructions comprise:
one or more VHSIC Hardware Description Language (VHDL) instructions.

15. The library of claim 1, where the executable instructions comprise:
one or more VERILOG instructions.

16. The library of claim 1, where a logic device represented by the logic device model is for use in one or more of the following environments:
in a power-generation environment;
in a well-drilling environment;
in space;
within or near a jet engine; or
within or near an internal-combustion engine.
